(19) United States
(12) Patent Application Publication
(10) Pub. No.: US 2023/0317472 A1
(43) Pub. Date: Oct. 5, 2023

(54) SCANNING SYSTEM

(71) Applicant: NVISANA, Yongin-si (KR)

(72) Inventors: Munsik OH, Suwon-si (KR); Jung-Hwan KIM, Suwon-si (KR); Tae-Hyung KIM, Suwon-si (KR)

(21) Appl. No.: 17/996,486

(22) PCT Filed: Apr. 19, 2021
(86) PCT No.: PCT/KR2021/004899

§ 371 Date: Oct. 18, 2022

(30) Foreign Application Priority Data
Apr. 18, 2020 (KR) 10-2020-0047058

(51) Int. Cl. H01L 21/67; H01L 21/02

(52) U.S. Cl. CPC H01L 21/67051; H01L 21/02052; H01L 21/6708

(57) ABSTRACT

The present invention relates to a scanning system, and more particularly, to a scanning system capable of scanning a bevel region of a wafer subjected to a standard sampling treatment and quickly cleaning a bevel nozzle used in a scanning step. For this purpose, the scanning system of the present invention includes a bevel scanning nozzle unit that has a nozzle groove, through which a bevel portion of a wafer enters and exits, at a lower end side of a bevel nozzle and that scans a bevel region of the wafer with a predetermined volume of a scanning solution; a wafer mounting unit that mounts the wafer thereon and rotates the wafer at a predetermined speed; and a nozzle cleaning unit that has a cleaning chamber filled with a cleaning solution and having a cleaning solution overflow portion and that immerses and cleans the bevel scanning nozzle unit.

### CROSS REFERENCE TO RELATED APPLICATIONS

The present application is a National Phase of International Application No. PCT/KR2021/004899 filed on Apr. 19, 2021, which claims the priority based on Korean Patent Application No. 10-2020-0047058 filed on Apr. 18, 2020, and the entire contents disclosed in the description and drawings of the corresponding applications are referenced in the present application.

### TECHNICAL FIELD

The present invention relates to a scanning system including a bevel scanning nozzle, and more particularly, to a scanning system that is formed with a structure that can facilitate the cleaning of the nozzle while smoothly performing bevel scanning, thereby significantly improving the usability of the scanning system.

### BACKGROUND OF THE INVENTION

With the recent high integration and high performance of semiconductor devices, semiconductor manufacturing processes are becoming more diverse and complex. In particular, it is essential to improve an analytical technique to solve problems occurring in each unit process.

Accordingly, a step of analyzing contaminants on the surface of a wafer is emerging as important in manufacturing semiconductor devices. In order to solve this, conventionally, a predetermined wafer is selected between individual semiconductor manufacturing lines and between individual manufacturing steps, the surface of the selected wafer is scanned to collect a contaminant sample for analysis of the contaminants on the surface of the wafer, and the collected contaminant sample is analyzed by destructive analysis methods such as atomic absorption spectroscopy and inductively coupled mass spectroscopy (ICP-mass spectroscopy) or non-destructive analysis methods such as total X-ray fluorescent analyzer.

In this case, a user takes out a substrate from a process chamber and then drops a scanning solution on the surface of the substrate, and the user directly and manually scans the surface of the substrate with the scanning solution to collect the contaminant sample for analyzing the contamination of the surface of the substrate. A semiconductor substrate contaminant collection device is known in Korean Registered Patent Publication No. 10-0383264. The semiconductor substrate contaminant collection device generally includes a process chamber, a transfer unit, a loader unit, a gas phase decomposition unit, a scanning unit, a drying unit, an unloader unit, and a central control unit for controlling the contaminant collection device as a whole. Here, the transfer unit, the loader unit, the gas phase decomposition unit, the scanning unit, the drying unit, and the unloader unit are installed in the process chamber, and is installed in the form of a semicircle in which the transfer unit is at a center and the loader unit and the unloader unit are at a starting point and an ending point, respectively. Here, the gas phase decomposition unit, the scanning unit, and the drying unit are sequentially installed between the loader unit and the unloader unit.

When a certain substrate is selected to analyze the degree of contamination of the substrate in a semiconductor manufacturing line and a semiconductor manufacturing process, the user transfers the substrate to the loader unit located in the process chamber of the contaminant collection device. Thereafter, when the user operates the contaminant collection device after sealing the process chamber, the transfer unit transfers the substrate located in the loader to a loading plate of the vapor phase decomposition unit, and the vapor phase decomposition unit seals the substrate transferred to the loading plate, and then, decompose an oxide film coated on the surface of the substrate by using the vapor of hydrofluoric acid.

Subsequently, when the decomposition of the oxide film coated on the surface of the substrate is completed, the transfer unit transfers the substrate located in the gas phase decomposition unit again to a substrate aligner of the scanning unit. Thereafter, the substrate aligner precisely aligns the positions of substrates transferred using an aligning hand. Simultaneously with this, the scanning unit is rotated to a nozzle tray position to insert a nozzle provided in the nozzle tray and then suction a predetermined amount of the scanning solution from a scanning solution bottle installed at the center of the nozzle tray, is moved to the top of the substrate, and slowly approaches the center of the substrate.

Subsequently, the scanning unit stops the approach when the center of the substrate and the nozzle inserted into the scanning unit are about to touch each other. When the approach is stopped, a pump pumps a part of the scanning solution suctioned into the nozzle through a pumping flow channel of the scanning unit to the surface of the substrate and causes the scanning solution to agglomerate in the form of water droplets between a lower end portion of the nozzle and the surface of the substrate.

In addition, the scanning unit scans the substrate in a step-by-step manner in which the substrate rotates once when the scanning unit moves once and the substrate rotates once again when the scanning unit moves once again. In this way, when the scanning of the substrate is completed without separation of the scanning solution from the lower end portion of the nozzle, the substrate aligner stops rotating and the scanning unit also stops moving, and the pump uses the pumping flow channel to suction all the scanning solution that has scanned the substrate into the nozzle. After that, the scanning unit is rotated to a sampling cup tray to discharge all the contaminant sample that has scanned the substrate into a sampling cup. When the discharge is completed, the scanning unit is rotated again so that the nozzle is located above the nozzle bottle, and then the nozzle installed in the scanning unit is separated from the scanning unit using a nozzle separation means installed in the scanning unit and falls in the nozzle bottle. Thereafter, the substrate is transferred to the unloader unit by the transfer unit and simultaneously unloaded to the outside, and a contaminant collection step is terminated.

As described above, the existing scanning nozzle has a structure that cannot scan an edge (corner) of the substrate. Moreover, since the existing scanning nozzle has a structure for recovering the contaminant sample but the analysis is performed in separate equipment, the existing scanning nozzle is not suitable for application to a production line that requires real-time analysis like these days.

In addition, there is a concern that a treatment liquid may be attached to the nozzle, and the treatment liquid may become an agglomerate and remain in the nozzle. When substrate treatment is performed with such an agglomerate attached to the nozzle, there is a concern that the agglomerate attached to the nozzle may be transferred to the substrate and the substrate may be soiled. Accordingly, in this type of substrate treatment device, there is a case where a nozzle cleaning device that removes the agglomerate or the like attached to the nozzle by cleaning the nozzle with the cleaning solution may be installed.

For example, Japanese Unexamined Patent Application Publication No. 2007-258462 discloses a nozzle cleaning device that removes an agglomerate attached to a nozzle by spraying a cleaning solution toward the nozzle from one side of the nozzle.

However, in the above prior literature, the nozzle cleaning step in nozzle cleaning takes a very long time, and the surface of the nozzle or a head portion of the nozzle can be cleaned well, but it is difficult to clean even a narrow region such as an inner surface or a groove of the nozzle in a short time.

### DETAILED DESCRIPTION OF THE INVENTION

### Technical Challenges

Accordingly, the present invention has been made to improve the conventional problems as described above, and an object of the present invention is to provide a scanning system capable of performing real-time analysis while recovering the contaminant sample on a wafer bevel region.

In addition, another object of the present invention is to provide a scanning system capable of uniformly scanning a predetermined wafer bevel region by correcting a relative distance between a wafer and a bevel nozzle with an image sensor.

In addition, a further object of the present invention is to provide a scanning system capable of inspecting whether the predetermined wafer bevel region is uniformly scanned by measuring the scanning powder remaining on the wafer.

In addition, a still further object of the present invention is to provide a scanning system capable of immersing and cleaning the bevel nozzle after a scanning step of the wafer bevel region.

In addition, a still further object of the present invention is to provide a scanning system capable of significantly reducing cleaning operation time by reducing a cleaning operation that takes a lot of time by performing cleaning several times to clean even the inside of the bevel nozzle in addition to the surface of the bevel nozzle in the conventional bevel nozzle cleaning.

### Technical Solution

In order to achieve the above technical challenges, a scanning system according to an aspect of the present invention is a device that scans a bevel region of a wafer with a bevel nozzle and cleans the bevel nozzle and is configured to include a bevel scanning nozzle unit that has a nozzle groove at a lower end side of the bevel nozzle capable of holding a scanning solution therein, the nozzle groove being formed so as to penetrate the bevel nozzle so that a bevel portion of the wafer enters and exits the bevel nozzle, and that scans a bevel region of the wafer with a predetermined volume of the scanning solution; a wafer mounting unit that mounts the wafer thereon and rotates the wafer at a predetermined speed; and a nozzle cleaning unit that has a cleaning chamber filled with a cleaning solution and having a cleaning solution overflow portion where the cleaning solution overflows, a cleaning solution injection port for injecting the cleaning solution filled in the cleaning chamber, and a cleaning solution discharge port for discharging the overflowing cleaning solution to the outside and that immerses and cleans the bevel scanning nozzle unit.

In addition, the scanning system according to the aspect of the present invention may include an image sensor that corrects a relative distance between the wafer and the bevel scanning nozzle unit, and the image sensor may measure the wafer in real time in addition to eccentricity amount data of the wafer while a scanning step is performed by the bevel scanning nozzle unit and perform a correction so that the wafer and the nozzle groove maintain a predetermined relative distance.

In addition, in the scanning system according to the aspect of the present invention, the wafer may be subjected to a standard sampling treatment by uniformly injecting a contaminant solution containing predetermined concentration and components, and scanning quality of the bevel region may be inspected by scanning the wafer bevel region subjected to the standard sampling treatment.

In addition, the scanning system according to the aspect of the present invention may further include an optical inspection device that measures whether or not contaminant solution powder remains on the wafer, and the optical inspection device may detect the contaminant solution powder provided in the wafer bevel region after the wafer scanning step to evaluate quality of the bevel scanning step.

In addition, in the scanning system according to the aspect of the present invention, the bevel nozzle may further include a cleaning port that is formed to be spaced apart by a predetermined distance upward from the nozzle groove and is provided so that a cleaning solution flows therethrough during the cleaning.

In addition, in the scanning system according to the aspect of the present invention, the nozzle cleaning unit may be configured to include a cleaning chamber provided with a cleaning solution overflowing portion and one or more cleaning solution injection holes that allow the cleaning solution to flow in a predetermined direction; a drain and collection portion that collects the cleaning solution overflowing from the cleaning chamber and discharges the cleaning solution to the cleaning solution discharge port; and a cleaning solution flow channel that connects the cleaning chamber and the cleaning solution injection port to each other.

In addition, in the scanning system according to the aspect of the present invention, the nozzle cleaning unit may include an auxiliary cleaning solution injection port that is connected to the cleaning solution flow channel and allows the auxiliary cleaning solution to be injected therethrough, thereby injecting the auxiliary cleaning solution into the cleaning chamber.

### Effects of the Invention

According to the means for solving the above challenges, the scanning system according to the present invention has the effect of significantly improving the utility of the system by recovering the contaminant sample including metal impurities on the wafer bevel region and analyzing the recovered scanning solution in real time.

In addition, the scanning system has the effect of correcting the relative distance between the wafer and the bevel nozzle with the image sensor to prevent any collision with the system and constantly scanning a predetermined wafer bevel region to perform a stable wafer scanning operation.

In addition, the scanning system has the effect of detecting the scanning solution powder not recovered by the scanning operation in the wafer bevel region with the optical inspection device to evaluate the quality of the wafer scanning operation, thereby ensuring a high-quality scanning step.

In addition, the scanning system has the effect of efficiently immersing and cleaning the bevel nozzle used in the scanning operation with the nozzle cleaning unit that immerses and cleans the bevel nozzle, thereby smoothly performing the preparation for the subsequent wafer scanning operation and quickly proceeding with the subsequent step without an excessive delay.

In addition, the scanning system has the effect that, when the bevel nozzle provided with the cleaning port through which the cleaning solution flows is provided and the bevel nozzle is immersed for cleaning after the scanning step, the cleaning solution enters and exits the inside and outside of the bevel nozzle through the cleaning port, so that the nozzle cleaning time can be significantly reduced compared to the existing bevel nozzle.

The effects of the present invention are not limited to the above effects, and it should be understood to include all effects that can be inferred from the configuration of the invention described in the detailed description or the claims of the present invention.

### BRIEF DESCRIPTION OF THE DRAWINGS

FIG. 1 shows a substrate contaminant analysis apparatus configured to include a scanning system according to an embodiment of the present invention.

FIG. 2 shows a structure of a wafer bevel region to be scanned according to the present invention.

FIG. 3 is an overall configuration diagram of the scanning system according to the embodiment of the present invention.

FIG. 4a shows a bevel scanning nozzle unit of the scanning system according to the embodiment of the present invention.

FIG. 4b shows a basic type of the bevel nozzle where it is provided with a nozzle groove into which the wafer bevel is inserted.

FIG. 4c shows a modified type of the bevel nozzle where it has a cleaning port through which the cleaning solution can flow additionally provided at a position above the nozzle groove.

FIG. 4d is a detail view of a nozzle groove in a bevel scanning nozzle unit.

FIG. 5a shows the scanning position correction of the scanning system according to the embodiment of the present invention.

FIG. 5b shows an exemplary state that the nozzle groove and the tip portion of the wafer are too close to each other.

FIG. 5c shows that the bevel scanning nozzle unit is moved and spaced apart in order to maintain a predetermined distance in the case of FIG. 5b.

FIG. 6. shows a standard sampling operation of the wafer bevel region due to forced contamination.

FIG. 7 shows the scanning quality inspection of the scanning system according to the embodiment of the present invention.

FIG. 8a is a perspective view of a nozzle cleaning unit of the scanning system according to the embodiment of the present invention.

FIG. 8b shows that a nozzle is cleaned by immersing the bevel nozzle in a second cleaning chamber up to the cleaning port.

FIG. 8c is a top plan view of a nozzle cleaning unit.

### BEST MODES FOR CARRYING OUT THE INVENTION

Hereinafter, the present invention will be described with reference to the accompanying drawings. However, the present invention may be embodied in several different forms and thus is not limited to an embodiment described herein.

Throughout the specification, when a certain portion is “coupled (connected, contacted, or combined)” with another portion, this includes not only “directly coupled” but also “indirectly coupled” with another member interposed therebetween. In addition, when a certain portion “includes” a certain component, this means that other components may be further included, rather than excluding the other components, unless otherwise stated.

The terms used in the present invention are used only to describe a specific embodiment and are not intended to limit the present invention. Singular expressions include plural expressions unless the singular expressions clearly indicate otherwise in context. In the present specification, it is to be understood that terms such as “include” or “have” are intended to designate that features, numbers, steps, operations, components, parts, or combinations thereof described in the specification are present and the possibility of the presence or addition of one or more other features, numbers, steps, operations, components, parts, or combinations thereof is not excluded in advance.

Hereinafter, a preferred embodiment of the present invention will be described with reference to the accompanying drawings so that persons having ordinary knowledge in the art can easily implement the invention.

The scanning system of the present invention is a device that scans a bevel region of a semiconductor wafer (or substrate) with a scanning solution to provide the scanned information to an analyzer. Here, the semiconductor wafer is typically a germanium wafer, a gallium arsenide wafer, a silicon wafer, or the like depending on a raw material, or a polished wafer, an epitaxial wafer, an SOI wafer, or the like depending on an additional process. Generally, the silicon wafer or the polished wafer is used. A wafer 1 of the present invention is not limited to any one, is preferably formed in a circular shape, and includes a SiN wafer.

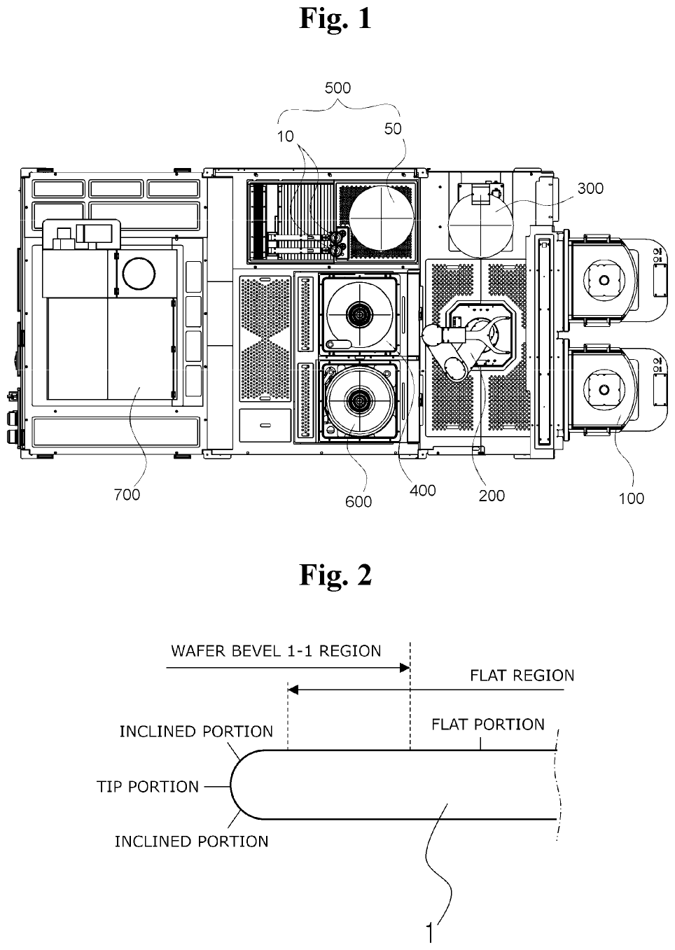

First, schematically referring to the embodiment of the present invention with reference to the respective drawings, FIG. 1 exemplarily shows a substrate contaminant analysis apparatus configured to include the scanning system according to the embodiment of the present invention, and the scanning system may constitute the substrate contaminant analysis apparatus together with a robot, an aligner unit, a VPD unit, an analyzer, and the like. FIG. 2 illustrates the structure of the wafer bevel region to be scanned according to the present invention, and the bevel region may be understood as a region including at least an inclined portion and a tip portion on the upper and lower surfaces of the wafer.

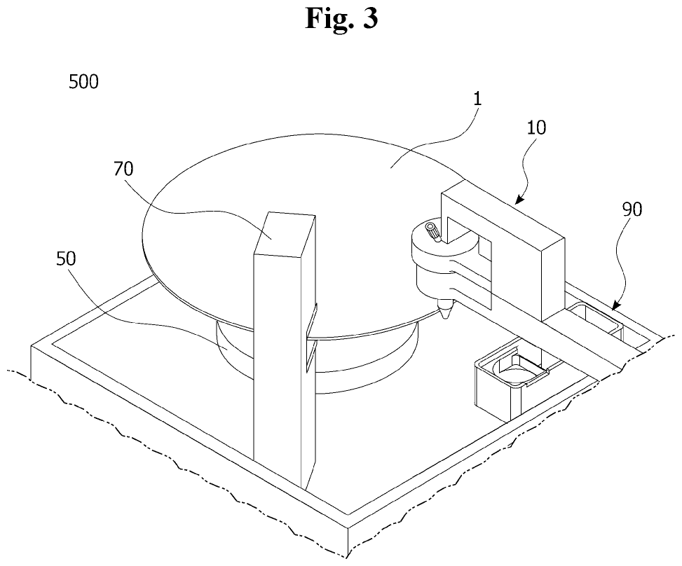

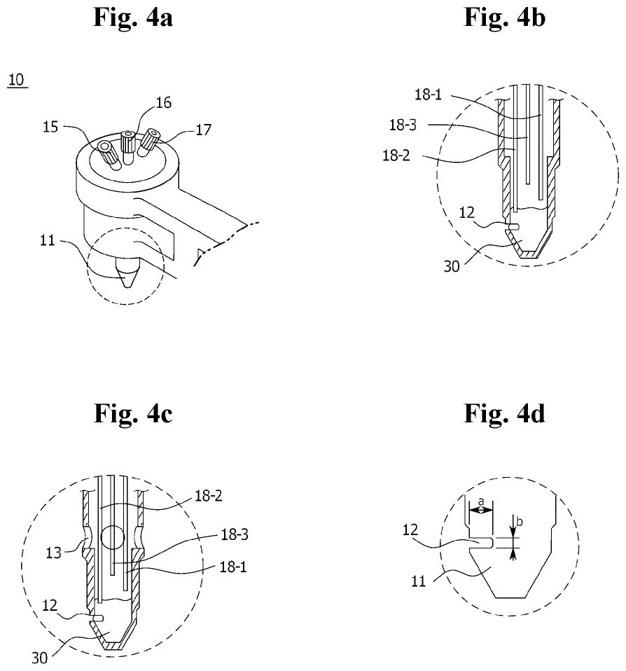

FIG. 3 is an overall configuration diagram of the scanning system according to the embodiment of the present invention and shows a bevel scanning nozzle unit 10 that scans the bevel region of the wafer 1, a wafer mounting unit 50 on which the wafer 1 is mounted, an image sensor 70 that detects the bevel position of the wafer 1 to supplement the scanning position of the bevel nozzle, and a nozzle cleaning unit 90 that immerses and cleans a bevel nozzle. FIG. 4a is a detailed diagram of the bevel scanning nozzle unit of the scanning system according to the embodiment of the present invention and shows the bevel scanning nozzle unit 10 including a bevel nozzle 11 formed with a nozzle groove 12 having therein a space in which a scanning solution is held and having the bevel region of the wafer 1 inserted thereinto, a cleaning port 13 through which a nozzle cleaning solution flows, an injection port 15 for injecting the scanning solution 30 into the bevel nozzle 11, and a discharge port 15 for discharging the scanning solution 30 from the bevel nozzle 11, and an air control port 17, which is a path for supplying air or gas to an internal space of the bevel nozzle.

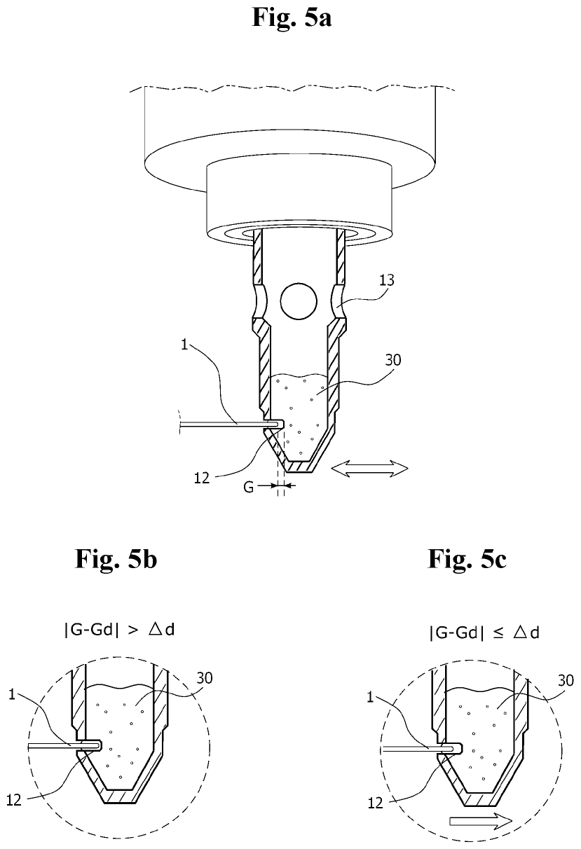

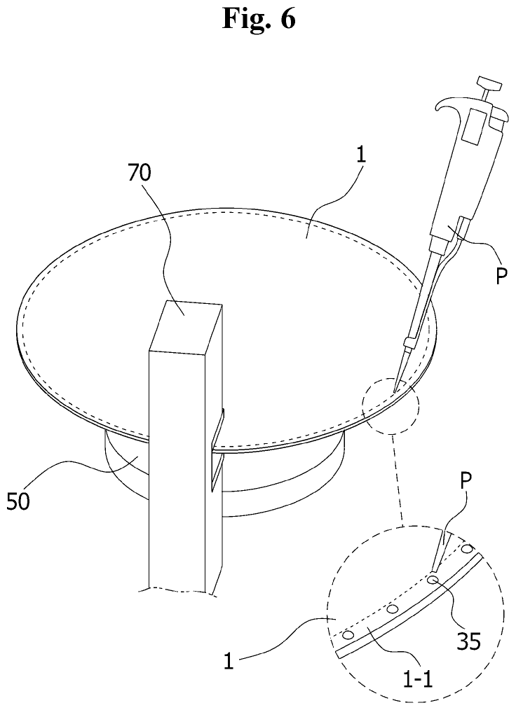

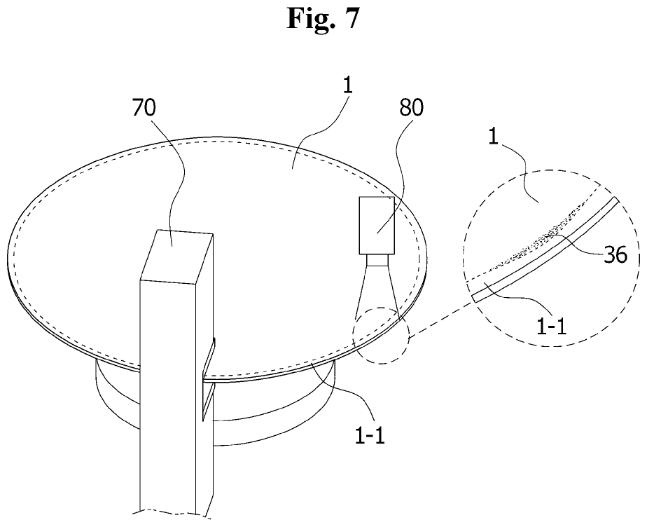

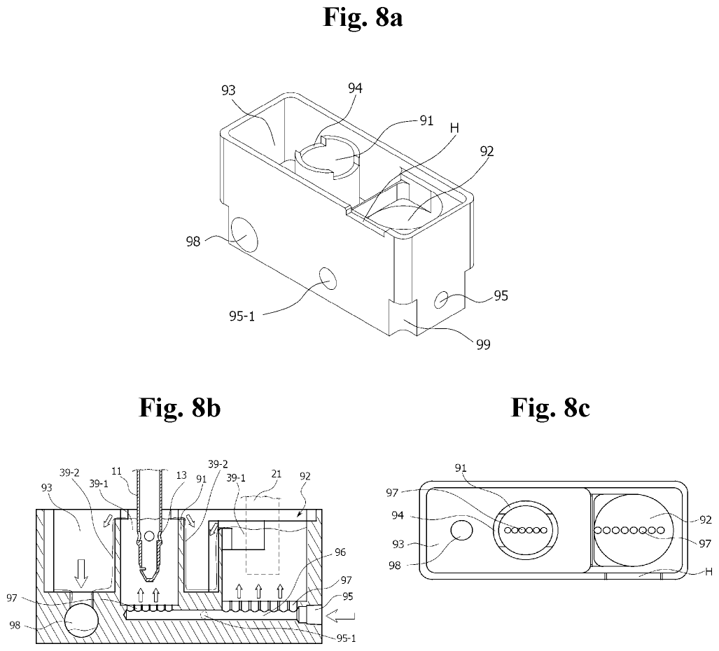

FIG. 5a shows the scanning position correction of the scanning system according to the embodiment of the present invention and shows that uniform bevel scanning quality is ensured by detecting the bevel position of a rotating wafer with an image sensor disposed at a position ahead of a scanning nozzle to control the scanning position of the bevel scanning nozzle that is performing a scanning operation from the rear. FIG. 6 shows a standard sampling operation of the wafer bevel region due to forced contamination and shows that a contaminant solution is uniformly injected into the bevel region of the wafer 1. FIG. 7 shows a scanning quality inspection process of the scanning system according to the embodiment of the present invention and shows whether or not the bevel region is uniformly scanned or the like is inspected by measuring powder 31 remaining on the wafer 1 in an optical manner. FIG. 8a shows the nozzle cleaning unit of the scanning system according to the embodiment of the present invention, and FIG. 8a is a perspective view of the nozzle cleaning unit 90, FIG. 8b shows that a nozzle is cleaned by immersing the bevel nozzle 11 in a second cleaning chamber 92 up to the cleaning port 13, and FIG. 8c is a top plan view of the nozzle cleaning unit 90.

Next, prior to a detailed description of the scanning system according to the embodiment of the present invention, an entire configuration of the substrate contaminant analysis apparatus configured to include the scanning system according to the embodiment of the present invention is first described with reference to FIG. 1. The substrate contaminant analysis apparatus of the present invention includes a load port 100, a robot 200, an aligner unit 300, a VPD unit 400, a scanning system 500, a recycling unit 600, an analyzer 700, and the like.

The load port 100 is located on one side of the substrate contamination analysis apparatus and provides a passage for introducing a substrate into the substrate contamination analysis apparatus by opening a cassette in which the substrate is accommodated. The robot 200 grips the substrate to automatically transfer the substrate between individual components of the substrate contamination analysis apparatus, and specifically, transfers the substrates between the cassette of the load port 100, the aligner unit 300, the VPD unit 400, the scanning system 500, and the recycling unit 600. The aligner unit 300 performs a function of aligning the substrate, and in particular, is used to align the center of the substrate before the substrate is placed on the wafer mounting unit 50.

The VPD unit 400 is a vapor phase decomposition unit in which vapor phase decomposition (VPD) is performed on the substrate, includes an introduction port and a door for introducing the substrate, a process chamber, a load plate provided inside the process chamber, a wafer chuck assembly, an etching gas injection port, and the like, and etches the surface or bulk of the substrate with a gaseous etchant.

The scanning system 500 includes the bevel scanning nozzle unit 10 and the wafer mounting unit 50, and the wafer mounting unit 50 has seated thereon the substrate on which the vapor phase decomposition is performed in the VPD unit 400 and performs a function of rotating the substrate in the process of scanning the substrate using the bevel scanning nozzle unit 10 in a state in which the substrate is seated. The bevel scanning nozzle unit 10 is provided on one side of the wafer mounting unit 50 and includes the bevel nozzle 11 that approaches the substrate and supplies a scanning solution onto the substrate, and a bevel scanning nozzle unit arm that can move the position of the nozzle, for example, in triaxial directions in a state in which the nozzle is mounted on one end thereof. One or a plurality of the nozzles and the bevel scanning nozzle unit arms may be included. The scanning solution is supplied to the nozzle of the scanning system 500 through a flow channel, and a sample solution obtained by collecting contaminants with the supplied solution is transferred to the analyzer 700 through the flow channel.

The recycling unit 600 treats the substrate with a solution containing an acid-based or base-based chemical in order to recycle the substrate on which the contaminants have been collected, and may be configured to include the introduction port and the door for introducing the substrate, the process chamber, the load plate provided inside the process chamber, the wafer chuck assembly, the nozzle that sprays the solution, and the like.

The analyzer 700 receives and analyzes the sample solution from the nozzle of the scanning system 500 through the flow channel and analyzes the presence or absence of the contaminants included in the sample solution, the content of the contaminants, the concentration of the contaminants, or the like. As the analyzer 700, an Inductively Coupled Plasma Mass Spectrometry (ICP-MS) is preferred.

Also, the substrate contaminant analysis apparatus may additionally include a separate bulk gas phase decomposition unit (not shown) instead of gas phase decomposition of the bulk of the substrate in the VPD unit 400, or for example, a bulk unit may be configured instead of the recycling unit 600.

Moreover, the substrate contaminant analysis apparatus according to the embodiment of the present invention may include portions for automatic production and transfer of the scanning solution and an etching solution, generation and supply of an etching gas, transfer of the sample solution, and the like, and these portions are mainly configured on a side surface of or inside the substrate contaminant analysis apparatus.

Meanwhile, in the present invention, when the wafer bevel region to be scanned by the bevel scanning nozzle unit is described, as exemplarily shown in FIG. 2, typically, the upper surface of the wafer 1 includes a flat portion that is horizontal, flat, and circular, and an annular inclined portion that extends obliquely downward and outward from an outer end of the flat portion of the upper surface, and similarly, the lower surface of the wafer 1 has a flat portion that is horizontal, flat, and circular, and an annular inclined portion that extends obliquely upward and outward from an outer end of the flat portion of the lower surface. The inclined portions of the upper and lower surfaces are inclined with respect to the flat portions of the upper and lower surfaces, and an annular tip portion of the wafer 1 extends from the outer end of the inclined portion of the upper surface to the outer end of the inclined portion of the lower surface. Here, a wafer bevel 1-1 region is a portion including the inclined portion and the tip portion of the upper surface, and the inclined portion of the lower surface, and may include a portion of the flat portion together, and as shown in FIG. 2, the wafer bevel 1-1 region may have a parabolic cross-section, but is not limited thereto and may have a trapezoidal cross-sectional shape.

Hereinafter, when the scanning system 500 of the present invention is specifically described, as shown in FIGS. 3 to 8, the scanning system 500 according to the embodiment of the present invention is a device that scans the wafer bevel 1-1 region with the scanning solution with the bevel scanning nozzle unit 10 to provide the scanned information to the analyzer 700 and cleans the bevel scanning nozzle unit 10 before the next scanning, and may be configured to include, as a detailed configuration of the system, the bevel scanning nozzle unit 10 that scans the wafer bevel 1-1 region with the scanning solution 30 held in the internal space, the wafer mounting unit 50 that mounts the wafer 1 thereon and rotates the wafer 1 at a predetermined speed, the image sensor 70 that detects and provides the bevel position of the wafer 1 in order to correct the distance of the bevel scanning nozzle unit 10 relative to the wafer 1, the nozzle cleaning unit 90 that immerses and cleans the bevel scanning nozzle unit 10, and the like.

In addition, in order to check the scanning quality as necessary, after a standard sampling operation in which a contaminant solution 35 containing a known predetermined concentration and components is prepared and the contaminant solution 35 is uniformly injected onto the wafer bevel 1-1 region and dried before a wafer scanning step, the wafer bevel region 1-1 is scanned by the bevel scanning nozzle unit 10 holding the scanning solution 30, and the scanning solution is provided to the analyzer for analysis. Accordingly, the scanning quality can be checked at a basic level. The bevel scanning nozzle unit 10 is immersed and cleaned in the nozzle cleaning unit 90 before the next scanning step. A detailed description thereof will be presented below.

As shown in FIG. 4a, the bevel scanning nozzle unit 10 that scans the wafer bevel 1-1 region in the scanning system according to the embodiment of the present invention has the bevel nozzle 11 provided at a tip portion thereof and is movable by a control means (not shown) to approach the wafer rotated on the wafer mounting unit, retreat to a standby position, or move to a cleaning position. The bevel nozzle 11 has an internal space capable of holding the scanning solution 30, the nozzle groove 12 through which a bevel portion of the wafer enters and exits is provided at a lower portion of the bevel nozzle 11, and the injection port 15 for supplying the scanning solution to the bevel nozzle 11, the discharge port 16 for discharging the scanning solution after the scanning, and the air control port 17 for injecting or discharging air or gas into the bevel nozzle are provided at an upper portion of the nozzle part 10.

FIG. 4a shows the structure of the bevel scanning nozzle unit 10, FIG. 4b shows the bevel nozzle 11 provided with the nozzle groove 12 into which the wafer bevel 1-1 is inserted, FIG. 4c shows the bevel nozzle 11 having the cleaning port 13 through which the cleaning solution 39 can flow additionally provided at a position above the nozzle groove 12, and FIG. 4d shows the nozzle groove 12 in an enlarged manner. Before the scanning, the scanning solution 30 is injected into the bevel nozzle 11 through the injection port 15, and after the scanning is completed, the scanning solution 30 is recovered through the discharge port 16 and provided to the analyzer for use. During the scanning, it is possible to inject or recover air into the bevel nozzle 11 through the air control port 17. In addition, the injection and recovery of the scanning solution 30 is not limited to any one method. As shown in FIG. 4b and FIG. 4c, an option of providing flow paths along which separate tubes 18-1, 18-2, and 18-3 are inserted through the injection port 15, the discharge port 16, and the air control port 17 and enter the inside of the bevel nozzle 11 may be provided, and the injection port 15 and the discharge port 16 may be integrally formed as one in addition to being individually and separately formed and may be shared when the scanning solution 30 is injected or discharged.

In the scanning system according to the embodiment of the present invention, as previously described, the bevel nozzle 11 of the bevel scanning nozzle unit 10 has the internal space capable of holding the scanning solution 30, and the nozzle groove 12 through which the bevel portion of the wafer enters and exits is formed at a lower position of the bevel nozzle 11. Although the nozzle groove 12 forms a gap spaced apart from the bevel portion of the wafer, the surface tension phenomenon can prevent the scanning solution 30 from flowing out through the gap. FIG. 4d shows the nozzle groove 12 in an enlarged manner and exemplarily shows a depth a of the nozzle groove 12 and a width b of the nozzle groove 12. A predetermined volume of the scanning solution 30 injected into the bevel nozzle 11 is held in the nozzle groove 12 by the surface tension, and even when the wafer 1 inserted into the nozzle groove 12 rotates at a predetermined speed, the wafer bevel 1-1 region is scanned without drop-off of the scanning solution 30. The depth and width of the nozzle groove 12 are not limited to any one dimension, and the nozzle groove 12 may be manufactured in various sizes depending on standards such as the size of the wafer 1 and the shape of the bevel region but may be formed so that the depth a of the nozzle groove 12 is preferably 1 to 4 mm and the width b of the nozzle groove 12 exceeds, preferably, 0.3 to 2 mm.

In addition, the scanning solution 30 is a solution containing nitric acid and hydrofluoric acid, and the volume of the scanning solution 30 injected into the bevel nozzle 11 is preferably 100 ul to 2 ml, but the detailed configuration and volume of the scanning solution is not limited thereto and may be changed and implemented.

In the scanning system according to the embodiment of the present invention, the bevel nozzle 11 of the bevel scanning nozzle unit 10 includes one or more cleaning ports 13 formed at spots spaced apart by a predetermined length from a lower end of the bevel nozzle 11. The cleaning solution 39 of the nozzle cleaning unit 90 smoothly flows in and out through the cleaning port 13 during the immersion cleaning in the nozzle cleaning unit 90 to clean the inside of the bevel nozzle 11. The cleaning port 13 is not limited to any one shape or position and may be formed in a circular shape of a predetermined size so that the cleaning solution 39 enters and exits smoothly as shown in FIG. 4c, and may be provided at a spot spaced upward by a predetermined distance from the nozzle groove 12 so that a predetermined volume of the scanning solution 30 required for the scanning step can be stably held without being discharged to the cleaning port 13.

In addition, the scanning system according to the embodiment of the present invention includes a control means (not shown) for controlling the movement of the bevel scanning nozzle unit 10, and the control means causes the bevel scanning nozzle unit 10 to approach the wafer 1 or be separated from the wafer 1 to return to the standby position during the wafer bevel scanning. The method of controlling the bevel scanning nozzle unit 10 is not limited to any one, and the bevel scanning nozzle unit 10 may be controlled by an orthogonal robot or a rotary robot, and a direct control method performed by an operator, an indirect control method in which the operator controls the bevel scanning nozzle unit 10 with a preset program by inputting optional coordinate values, or the like may be adopted to transfer and control the bevel scanning nozzle unit 10 depending on the diameter of the wafer 1.

In addition, the scanning system according to the embodiment of the present invention may be configured to further include a tube 18 for injecting or recovering the scanning solution 30 or air, and the tube 18 may include at least any one of an injection tube 18-1 for injecting the scanning solution 30 into the bevel nozzle 11, a recovery tube 18-2 for recovering the scanning solution 30 into the bevel nozzle 11 through the discharge port 16, and an air tube 18-3 for injecting or discharging air or gas into the bevel nozzle 11 through the air control port 17. In this case, the recovery tube 18-2 needs to be disposed so as to enter a spot where the recovery tube 18-2 is immersed in the scanning solution 30 in the bevel nozzle 11, and it is preferable that the injection tube 18-1 enters a predetermined spot where the injection tube 18-1 does not come into contact with the scanning solution 30 in the bevel nozzle 11. In addition, it is preferable that the air tube 18-3 enters a predetermined spot where the scanning solution 30 does not reach, and in the case of the bevel nozzle 11 provided with the cleaning port 13, it is preferable that the air tube 18-3 enters a spot past the cleaning port 13. In addition, the timing when the scanning solution 30 flows into the bevel nozzle 11 is not limited to any one, and the scanning solution 30 may flow into the bevel nozzle 11 at at least any one timing out of the timings before and after the wafer 1 is inserted while the wafer 1 is inserted into the nozzle groove 12.

In addition, the scanning system may include a plurality of the bevel scanning nozzle units 10 that scan the wafer bevel 1-1. Bevel nozzles 11 formed with nozzle grooves 12 of different sizes may be included, and a bevel nozzle 11 provided with a nozzle groove 12 suitable for the thickness or shape of a wafer to be scanned may be selectively driven to perform the bevel scanning to increase the responsiveness of wafer scan analysis. In addition, a configuration may be adopted in which the surface of the wafer 1 is separately scanned by further including a surface scanning nozzle (not shown), which holds and scans the scanning solution 30 between the surface scanning nozzle and the surface of the wafer, at the lower portion of the tip portion.

In addition, the scanning system according to the embodiment of the present invention includes the wafer mounting unit 50 on which the wafer 1 is mounted, and the wafer mounting unit 50 rotates the wafer 1 mounted at the center at a predetermined rotation speed. For example, the rotation speed is preferably 5 degree/sec but is not limited thereto. The wafer mounting unit 50 is not limited to any one method, and it is preferable that the drop-off of the wafer 1 is prevented by a method such as vacuum suction. In addition, the wafer mounting unit 50 may be configured to rotate only in a case where the wafer 1 is seated by a contact sensor or the like, and a method of transferring the wafer 1 after being aligned by an aligning means so that a center point of the wafer 1 can be aligned with the center of the aligning means and mounting the wafer 1 on the wafer mounting unit 50 may be employed.

In addition, the scanning system according to the embodiment of the present invention includes the image sensor 70 that corrects the relative distance between the bevel scanning nozzle unit 10 and the wafer 1, and as shown in FIG. 5a, during the scanning operation performed by the bevel nozzle 11, the relative distance between the nozzle groove 12 and the wafer bevel 1-1 is adjusted so that the predetermined wafer bevel 1-1 region is uniformly scanned by the image sensor 70. FIG. 5a shows that the nozzle groove 12 and the tip portion of the wafer 1 maintain a predetermined distance from each other by means of the image sensor 70, and FIG. 5c exemplarily shows that the bevel scanning nozzle unit 10 is moved and spaced apart so that the predetermined distance is maintained in a case where the nozzle groove 12 and the tip portion of the wafer are too close to each other as exemplarily shown in FIG. 5b. That is, a control is performed so that a distance G between the nozzle groove 12 and the tip portion of the wafer 1 is maintained within an allowable range Δd based on a predetermined reference distance Gd. In addition, in the above example, although a horizontal distance between the nozzle groove 12 and the tip portion of the wafer 1 has been mainly described, the control of maintaining a predetermined distance from each other can be extended and provided with respect to a vertical distance.

Here, the image sensor 70 is preferably a charge coupled device (CCD) type image sensor but is not limited thereto. A phenomenon in which the bevel region of the wafer 1 is non-uniformly scanned due to the eccentricity of the wafer 1 or the non-uniformity of the shape of the wafer including the wafer bevel 1-1 region despite precise position control of the bevel scanning nozzle unit 10 itself can be minimized. In the method of correcting the relative distance, it is preferable to perform the position correction of the bevel scanning nozzle unit 10 during the scanning operation of the bevel scanning nozzle unit 10 by measuring the bevel region or the outermost position of the wafer in real time with the image sensor 70 at a position ahead of the bevel scanning nozzle unit 10. The position correction is not limited thereto, and more precise position correction may be performed by additionally reflecting data on the eccentricity amount, deflection amount, or the like of the wafer 1.

Meanwhile, as shown in FIG. 6, the scanning system according to the embodiment of the present invention includes a scanning quality inspection or correction procedure including a step of injecting the contaminant solution 35 containing predetermined concentration and components. By means of the scanning step, the wafer bevel 1-1 region is subjected to standard sampling treatment to perform a scanning preparation operation. Here, a method of injecting 2 ul of the contaminant solution 35 fifty times is not limited thereto. The contaminant solution injection is not limited to any one method, and the contaminant solution 35 may be uniformly injected into the wafer bevel 1-1 region rotated at a predetermined speed by the wafer mounting unit 50 with a pipette P typically used. In addition to the injection by the operator, a separate injection control device such as an orthogonal robot or a rotary robot may be further provided to allow uniform injection in a predetermined region with the injection control device.

The contaminant solution 35 is a solution containing predetermined concentration and components such as metal impurities, and the metal impurities are a solution in which iron (Fe), nickel (Ni), and copper (Cu) are mixed in a predetermined ratio. In addition, at least one of sodium (Na), magnesium (Mg), aluminum (Al), calcium (Ca), titanium (Ti), chromium (Cr), and zinc (Zn) may be additionally mixed. The contaminant solution 35 having a contaminant concentration of 1 ppb is preferred, but the contaminant solution is not limited thereto, and the contaminant solution may be prepared by selecting the contaminant concentration within a predetermined range.

In addition, a step of removing an oxide film on the surface of the wafer 1 before the contaminant solution 35 is injected may be further included, and the contaminant solution 35 is glued in a predetermined water droplet shape without being spread through the oxide film removal step. As the method of removing the oxide film, it is preferable to use HF vapor and put the wafer 1 into a chamber filled with HF vapor, but the method is not limited thereto. An HF solution may be used to remove the oxide film, or a gas in which the HF vapor is mixed with hydrogen peroxide or the like may be used to remove the oxide film.

In addition, a drying step of drying the contaminant solution 35 injected into the wafer bevel 1-1 region may be included, and metal components, particles, or the like added to the contaminant solution 35 through the drying step are attached to the surface of the wafer 1 to complete the scanning preparation operation for scanning quality inspection. The drying method is not limited to any one method, and a natural drying method or a forced drying method may be adopted, and as the forced drying method, drying by heat treatment performed in a separate chamber or drying by predetermined gas injection may be adopted.

As shown in FIG. 7, the scanning system according to the embodiment of the present invention may be configured to include an optical inspection device 80 that inspects whether or not contaminant solution powder 36 remains and the degree of remaining on the surface of the wafer 1 after the scanning, and whether or not the predetermined wafer bevel 1-1 region is uniformly scanned is inspected by the optical inspection device 80. The optical inspection device 80 may be automatic optical inspection equipment but is not limited thereto. When the contaminant solution 35 undergoes the drying step, the contaminant solution powder 36, which is a white-colored residue, remains on the wafer 1, and after the scanning, the contaminant solution powder 36 still remains on a region that is not scanned with the scanning solution 30. The contaminant solution powder 36 on a scanning path during the scanning operation is recovered and removed together with the impurities on the wafer bevel 1-1 region, As for the contaminant solution powder 36 missing from the scanning path during the scanning operation, it is possible to evaluate the quality of the scanning operation by determining whether or not the contaminant solution powder 31 remains on the surface of the wafer 1 with the optical inspection device 80. The measurement method performed by the optical inspection device 80 is preferably to inspect predetermined points in the wafer bevel 1-1, but is not limited thereto, and all of the wafer bevel 1-1 region may be measured, and a method of measuring the wafer bevel 1-1 that is being rotated by the wafer 50, a method of measuring the wafer bevel 1-1 while the optical inspection device 80 is moved by a control robot, or the like may be employed.

Meanwhile, the scanning solution 30 containing the impurities recovered during the scanning step according to the present invention is provided to the analyzer (not shown) after recovery and undergoes a scanning solution analysis step such as a predetermined chemical analysis, and the chemical analysis is a trace element analysis method and includes inductively coupled plasma atomic emission spectroscopy (ICP-AES), inductively coupled plasma mass spectrometry (ICP-MS), or the like, and the scanning solution analysis step is preferably performed by the inductively coupled plasma mass spectrometry (ICP-MS) but is not limited thereto.

As shown in FIG. 8a, the scanning system according to the embodiment of the present invention includes the nozzle cleaning unit 90 in which the bevel scanning nozzle unit 10 is immersed and cleaned, and the cleaning solution 39 is continuously injected through a cleaning solution injection port 95 of the nozzle cleaning unit 90, and the cleaning solution 39 passes through cleaning chambers 91 and 92 and is discharged through a cleaning solution discharge port 98. The nozzle cleaning unit 90 includes the first cleaning chamber 91 in which the cleaning solution 39 is filled and the bevel nozzle 11 is immersed, the second cleaning chamber 92 in which the cleaning solution 39 is filled and the other scanning nozzles 21 are immersed, a drain and collection portion 93 through which the overflowing cleaning solution 39 is collected and drained, the cleaning solution injection port 95 into which the cleaning solution 39 is injected, and the cleaning solution discharge port 98 through which the cleaning solution 39 is discharged, and one more mounting grooves 99 for fixing and installing the cleaning solution discharge port 98 and the cleaning solution cleaning unit 90 to the device. A cleaning solution 39-1 injected through the cleaning solution injection port 95 passes through a cleaning solution flow channel 96 and is filled in the first cleaning chamber 91 and the second cleaning chamber 92, and a cleaning solution 39-2 overflowing out of the chambers is discharged from the drain and collection portion 93 to the outside through the cleaning solution discharge port 98.

As the cleaning solution 39, a solution containing water or deionized water (hereinafter referred to as ‘DI water’) may be used, and the cleaning solution 39 made of DI water is preferable but is not limited thereto.

In addition, the first cleaning chamber 91 and the second cleaning chamber 92 are not limited to any one configuration and shape, and the first cleaning chamber 91 may be formed to have a predetermined clearance from the nozzle cleaning unit 90 and may include one or more cleaning solution overflow portions 94 to prevent the overflowing cleaning solution 39 from flowing out of the nozzle cleaning unit 90. In addition, the second cleaning chamber 92 may be integrally formed with the nozzle cleaning unit 90 and has a step with a relatively lower outer surface provided on one side to prevent the overflowing cleaning solution 39 from flowing out to the outside. In addition, the first cleaning chamber 91 and the second cleaning chamber 92 may be used without being limited to a nozzle having a specific shape, and immersing a specific nozzle in the first cleaning chamber 91 and the second cleaning chamber 92, or separately immersing different nozzles in the first cleaning chamber 91 and the second cleaning chamber 92, respectively, for cleaning may be selected and employed as necessary. In addition, the nozzle cleaning unit 90 may be configured to further include a stepped discharge groove (H) at an upper end portion of an outer surface thereof, so that the cleaning solution 39-2 flowing out of the nozzle cleaning unit 90 in a malfunctioning situation, such as the cleaning solution discharge port 98 being blocked due to foreign substances or the like, can be discharged quickly in an intended direction.

In addition, as shown in FIG. 8b, the cleaning solution flow channel 96, which is a flow channel of the first cleaning chamber 91 and the second cleaning chamber 92, may be further included, and the cleaning solution flow channel 96 allows the cleaning solution 39 injected through the cleaning solution injection port 95 to flow into the first cleaning chamber 91 and the second cleaning chamber 92 via a cleaning solution injection hole 97. The cleaning solution flow channel 96 is not limited to any one but is formed to extend in a longitudinal direction so that the first cleaning chamber 91 and the second cleaning chamber 92 are connected to each other. Accordingly, as shown in FIG. 8c, it is preferable that a plurality of the cleaning solution injection holes 97 are provided so that the cleaning solution 39 is uniformly injected into the chamber. In addition, the cleaning solution flow channel 96 may be formed as a single flow channel that connects the first cleaning chamber 91 and the second cleaning chamber 92 to each other. Besides, an option is also possible in which the cleaning solution flow channels 96 are separately formed in the first cleaning chamber 91 and the second cleaning chamber 92.

In addition, an auxiliary cleaning solution injection port 95-1 for injecting a functional auxiliary cleaning solution such as a chemical solution in addition to the cleaning solution 39 may be further included, and a chemical solution or the like in addition to the cleaning solution 39 is additionally injected into the first cleaning chamber 91 or the second cleaning chamber 92 by the auxiliary cleaning solution injection port 95-1. A method may be adopted in which the auxiliary cleaning solution injection port 95-1 is formed between the cleaning solution injection hole 97 of the first cleaning chamber 91 and the cleaning solution injection hole 97 of the second cleaning chamber 92 in the cleaning solution flow channel 96 formed in the longitudinal direction to allow a chemical solution or the like separately injected as necessary to flow only into the second cleaning chamber 92.

In addition, when a cleaning step of the bevel nozzle 11 provided with the cleaning port 13 is described, the nozzle cleaning step is performed by completely immersing the bevel nozzle 11, in which the cleaning port 13 is provided in the first cleaning chamber 91, in the cleaning solution 39, and the bevel nozzle 11 can be more quickly clean by this cleaning structure. In a case where an attempt to clean the bevel nozzle 11 of FIG. 4b is made, a process of immersing the bevel nozzle 11 in the cleaning solution 39 in order to remove the impurities, the scanning solution 30 or the like remaining in the nozzle should be repeatedly performed about 15 to 20 times to clean even the inside of the nozzle. Even in a case where the bevel nozzle 11 is cleaned through a device that forcibly sprays the cleaning solution 39 toward the bevel nozzle 11, it is not smooth to carefully clean up even the nozzle groove 12 in addition to the inside of the nozzle, and there are also disadvantages in terms of complexity and manageability of the device. In contrast, the bevel nozzle 11 provided with the cleaning port 13 is immersed in the first cleaning chamber 91, and the cleaning solution 39 continuously injected from the cleaning solution injection hole 97 is made to flow through the cleaning port 13 for cleaning. Accordingly, it is possible to obtain the effects that even the inner surface of the bevel nozzle 11 in addition to the outer surface of the bevel nozzle 11 and the nozzle groove 12 can be effectively cleaned, and the time for the cleaning step can be significantly shortened.

In addition, a step of drying the bevel nozzle 11 immersed in the nozzle cleaning unit 90 is further included, the bevel nozzle 11 taken out from the nozzle cleaning unit 90 is dried, and the cleaning solution 39 remaining on the outer surface and the inner surface of the bevel nozzle 11 is dried to complete the preparation for the next scanning step. The drying method is not limited to any one method, and a natural drying method or a forced drying method may be adopted, and the forced drying method is preferably drying performed by spraying a predetermined gas to a nozzle.

In addition to this, the description of the present invention described above is for illustrative purpose only, and persons having ordinary knowledge in the art to which the present invention pertains will be able to understand that the present invention can be easily modified into other specific forms without changing the technical spirit or essential features of the present invention. Therefore, it should be understood that the embodiment described above is merely illustrative in all respects and not restrictive. For example, each component described as a single type may be implemented in a distributed or divided form, and similarly, components described in distributed or divided forms may also be implemented in a combined form within the scope understood by persons having ordinary skill in the art. In addition, the steps of the method may be implemented separately multiple times or may be implemented multiple times in combination with at least any other step.

The scope of the present invention is indicated by the following claims, and all changes or modified forms derived from the meaning and scope of the claims and their equivalent concept should be construed as being included in the scope of the present invention.

### EXPLANATION OF REFERENCE NUMERALS

500: SCANNING SYSTEM
1: WAFER
1-1: WAFER BEVEL
10: BEVEL SCANNING NOZZLE UNIT
11: BEVEL NOZZLE
12: NOZZLE GROOVE
13: CLEANING PORT
15: INJECTION PORT
16: DISCHARGE PORT
17: AIR CONTROL PORT
18: TUBE
30: SCANNING SOLUTION
35: CONTAMINANT SOLUTION
36: CONTAMINANT SOLUTION POWDER
39: CLEANING SOLUTION
50: WAFER MOUNTING UNIT
70: IMAGE SENSOR
80: OPTICAL INSPECTION DEVICE
90: NOZZLE CLEANING UNIT
91: FIRST CLEANING CHAMBER
92: SECOND CLEANING CHAMBER
93: DRAIN AND COLLECTION PORTION
94: CLEANING SOLUTION OVERFLOW PORTION
95: CLEANING SOLUTION INJECTION PORT
96: CLEANING SOLUTION FLOW CHANNEL
97: CLEANING SOLUTION INJECTION PORT
98: CLEANING SOLUTION DISCHARGE PORT
99: MOUNTING GROOVE
P: PIPETTE
H: DISCHARGE GROOVE

1. A scanning system that scans a bevel region of a wafer with a bevel nozzle and cleans the bevel nozzle, comprising:
a bevel scanning nozzle unit (10) that has a nozzle groove (12) at a lower end side of the bevel nozzle (11) capable of holding a scanning solution (30) therein, the nozzle groove (12) being formed so as to penetrate the bevel nozzle (11) so that a bevel portion of the wafer (1) enters and exits the bevel nozzle (11), and that scans a bevel region of the wafer with a predetermined volume of the scanning solution (30);
a wafer mounting unit (50) that mounts the wafer 1 thereon and rotates the wafer (1) at a predetermined speed; and
a nozzle cleaning unit (90) that has a cleaning chamber filled with a cleaning solution (39) and having a cleaning solution overflow portion (94) where the cleaning solution (39) overflows, a cleaning solution injection port (95) for injecting the cleaning solution filled in the cleaning chamber, and a cleaning solution discharge port (98) for discharging the overflowing cleaning solution to the outside and that immerses and cleans the bevel scanning nozzle unit (10).

2. The scanning system according to claim 1, further comprising:
an image sensor (70) that corrects a relative distance between the wafer (1) and the bevel scanning nozzle unit (10),
wherein the image sensor (70) measures the wafer (1) in real time in addition to eccentricity amount data of the wafer (1) while a scanning step is performed by the bevel scanning nozzle unit (10) and performs a correction so that the wafer (1) and the nozzle groove (12) maintain a predetermined relative distance.

3. The scanning system according to claim 2,
wherein the wafer (1) is subjected to a standard sampling treatment by uniformly injecting a contaminant solution (35) containing predetermined concentration and components, and scanning quality of the bevel region is inspected by scanning the wafer bevel region subjected to the standard sampling treatment.

4. The scanning system according to claim 3, further comprising:
an optical inspection device (80) that measures whether or not contaminant solution powder (36) remains on the wafer (1),
wherein the optical inspection device (80) detects the contaminant solution powder (31) provided in the wafer bevel region after the wafer scanning step to evaluate quality of the bevel scanning step.

5. The scanning system according to claim 1,
wherein the bevel nozzle (11) further includes a cleaning port (13) that is formed to be spaced apart by a predetermined distance upward from the nozzle groove (12) and is provided so that the cleaning solution (39) flows therethrough during the cleaning.

6. The scanning system according to claim 1,
wherein the nozzle cleaning unit (90) is configured to include:
a cleaning chamber provided with a cleaning solution overflowing portion (94) and one or more cleaning solution injection holes (97) that allow the cleaning solution to flow in a predetermined direction and;
a drain and collection portion (93) that collects the cleaning solution overflowing from the cleaning chamber and discharges the cleaning solution to the cleaning solution discharge port (98); and
a cleaning solution flow channel (96) that connects the cleaning chamber and the cleaning solution injection port (95) to each other.

7. The scanning system according to claim 6,
wherein the nozzle cleaning unit (90) includes an auxiliary cleaning solution injection port (95-1) that is connected to the cleaning solution flow channel (96) and allows the auxiliary cleaning solution to be injected therethrough, thereby injecting the auxiliary cleaning solution into the cleaning chamber.
